(19) United States
(12) Patent Application Publication
(10) Pub. No.: US 2024/0324171 A1
(43) Pub. Date: Sep. 26, 2024

(54) SEMICONDUCTOR DEVICE AND METHOD OF MANUFACTURING SEMICONDUCTOR DEVICE

(71) Applicant: Kioxia Corporation, Minato-ku, Tokyo (JP)

(72) Inventors: Tsuyoshi SUGISAKI, Yokkaichi Mie (JP); Takeru MAEDA, Yokkaichi Mie (JP); Kotaro NODA, Yokkaichi Mie (JP)

(73) Assignee: Kioxia Corporation, Minato-ku, Tokyo (JP)

(21) Appl. No.: 18/593,049

(22) Filed: Mar. 1, 2024

(30) Foreign Application Priority Data
Mar. 20, 2023 (JP) 2023-043808

(51) Int. Cl. H10B 12/00

(52) U.S. Cl. CPC H10B 12/05; H10B 12/315

(57) ABSTRACT

A semiconductor device includes: a first electrode, a first insulating layer, a second insulating layer, and a second electrode arranged in a stacking direction; a gate electrode interposed between the first and second insulating layers in the stacking direction, and extending in a first direction; and a channel layer penetrating the gate electrode and coupled to the first electrode and the second electrode. The channel layer has a first cross-sectional area at a height position of the first insulating layer and a second cross-sectional area at a height position of the gate electrode, the first cross-sectional area is larger than the second cross-sectional area. The gate electrode has a wider width at a penetrating portion of the channel layer than any other portions in a second direction intersecting the stacking direction and the first direction.

### CROSS-REFERENCE TO RELATED APPLICATION

This application is based upon and claims the benefit of priority from Japanese Patent Application No. 2023-043808, filed Mar. 20, 2023, the entire contents of which are incorporated herein by reference.

### FIELD

Embodiments described herein relate generally to a semiconductor device and a method of manufacturing a semiconductor device.

### BACKGROUND

A semiconductor device configured as a vertical transistor having a composite oxide semiconductor as a channel layer is known. The channel layer penetrates each of a plurality of gate electrodes extending in a predetermined direction, whereby a voltage is applied from the gate electrode to each of a plurality of the channel layers.

In recent years, a demand for reduction in size of the semiconductor device increases, and it is desirable to arrange the plurality of gate electrodes at high density.

### DESCRIPTION OF THE DRAWINGS

FIGS. 1A to 1C are schematic diagrams showing an example of a configuration of a semiconductor device according to Embodiment 1.

FIGS. 2A to 2G are cross-sectional views sequentially illustrating a part of a procedure of a method of manufacturing the semiconductor device according to Embodiment 1.

FIGS. 3AA to 3DB are cross-sectional views sequentially illustrating a part of the procedure of the method for manufacturing the semiconductor device according to Embodiment 1.

FIGS. 4A to 4G are cross-sectional views sequentially illustrating a part of the procedure of the method of manufacturing the semiconductor device according to Embodiment 1.

FIGS. 5A and 5B are XY cross-sectional views at height positions of gate electrodes of semiconductor devices according to an embodiment and a comparative example.

FIGS. 6A and 6B are schematic diagrams showing an example of a configuration of a semiconductor device according to Embodiment 2.

FIGS. 7AA to 7DB are cross-sectional views sequentially illustrating a part of a procedure of a method for manufacturing the semiconductor device according to Embodiment 2.

FIGS. 8A to 8H are cross-sectional views sequentially illustrating a part of the procedure of the method of manufacturing the semiconductor device according to Embodiment 2.

FIGS. 9A and 9B are schematic diagrams showing an example of a configuration of a semiconductor device according to a modification example of Embodiment 2.

### DETAILED DESCRIPTION

Embodiments provide a semiconductor device and a method of manufacturing a semiconductor device, in which a plurality of gate electrodes can be arranged at high density using a simple method.

In general, according to one embodiment, a semiconductor device includes: a first electrode; a first insulating layer provided over the first electrode in a stacking direction; a second insulating layer provided over the first insulating layer in the stacking direction; a second electrode provided over the second insulating layer in the stacking direction; a gate electrode interposed between the first and second insulating layers in the stacking direction, and extending in a first direction intersecting the stacking direction; a channel layer penetrating the gate electrode, extending in the stacking direction, having a first end connected to the first electrode, and having a second end connected to the second electrode; and a gate insulating layer provided between the first insulating layer, the gate electrode, and the second insulating layer, and the channel layer. The channel layer has a first cross-sectional area at a height position of the first insulating layer and a second cross-sectional area at a height position of the gate electrode, the first cross-sectional area is larger than the second cross-sectional area. The gate electrode has a wider width at a penetrating portion of the channel layer than any other portions in a second direction intersecting the stacking direction and the first direction.

Hereinafter, embodiments of the present disclosure will be described in detail with reference to the drawings. The present disclosure is not limited to the following embodiments. The elements in the following embodiments include those that can be easily assumed by those skilled in the art or those that are substantially the same.

### Embodiment 1

Hereinafter, Embodiment 1 will be described in detail with reference to the drawings. Structure Example of Semiconductor Device

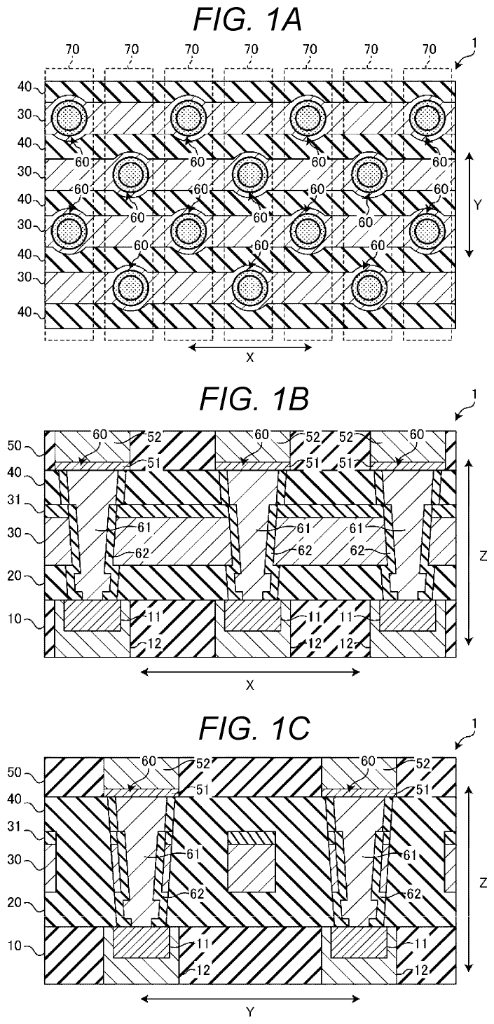

FIGS. 1A to 1C are schematic diagrams showing an example of a configuration of a semiconductor device 1 according to Embodiment 1. FIG. 1A is an XY cross-sectional view of the semiconductor device 1 at a height position of a gate electrode 30 to be described below. FIG. 1B is a cross-sectional view of the semiconductor device 1 in an X direction. FIG. 1C is a cross-sectional view of the semiconductor device 1 in a Y direction.

In the present specification, both the X direction and the Y direction are directions along a surface of the gate electrode 30 to be described below, and the X direction and the Y direction are orthogonal to each other. A Z direction is a direction orthogonal to the X direction and the Y direction, and is a stacking direction of each layer provided in the semiconductor device 1.

In addition, the extension direction of the gate electrode 30 may be referred to as a first direction, and the first direction is a direction along the X direction. In addition, a direction that is an extension direction of a bit line 70 to be described below and intersects the first direction may be referred to as a second direction, and the second direction is a direction along the Y direction. Since the semiconductor device 1 may include a manufacturing error, the first direction and the second direction are not necessarily orthogonal to each other.

As shown in FIGS. 1A to 1C, the semiconductor device 1 includes a lower electrode 11 as the first electrode, a gate electrode 30, an upper electrode 51 as the second electrode, and a pillar 60.

The lower electrode 11, the gate electrode 30, the upper electrode 51, and the pillar 60 are provided above a substrate (not shown) such as a silicon substrate. More specifically, insulating layers 10 and 20, the gate electrode 30, and insulating layers 40 and 50 are provided in this order above the substrate. Layer thicknesses of the gate electrode 30 and the insulating layers 20 and 40 are, for example, about several tens of nanometers.

The insulating layer 10 is, for example, a silicon nitride layer. Contacts 12 penetrating the insulating layer 10 are provided in the insulating layer 10 at predetermined intervals in the X direction and the Y direction. The contact 12 is, for example, an amorphous silicon layer or the like, and is connected to the substrate directly or via a source line (not shown).

The lower electrode 11 formed of, for example, an indium tin oxide (ITO) layer is buried in the contact 12. Thereby, the potential of the lower electrode 11 falls to the potential of the substrate. Upper surfaces of the insulating layer 10, the contact 12, and the lower electrode 11 are located on substantially the same plane, and the upper surface of the lower electrode 11 is not covered with the contact 12 or the insulating layer 10.

The insulating layer 20 that covers the upper surfaces of the insulating layer 10, the contact 12, and the lower electrode 11 is provided on the insulating layer 10. The insulating layer 20 as the first insulating layer is, for example, a SiO layer. The insulating layer 20 may be a Low-k layer such as a SiOC layer or an air gap layer.

A plurality of gate electrodes 30 extending in the direction along the X direction and arranged at predetermined intervals in the Y direction are provided on the insulating layer 20. The plurality of gate electrodes 30 are formed of a tungsten layer or the like, and are provided at positions overlapping, in the Z direction, the lower electrodes 11 arranged in a grid shape in the X direction and the Y direction.

As will be described below, the pillar 60 is provided at each position overlapping the lower electrode 11 in the Z direction, penetrating the gate electrode 30. A width in the direction along the Y direction of the gate electrode 30 extending in the direction along the X direction, that is, a width in a direction intersecting the extension direction of the gate electrode 30 is, for example, equal to or less than a width of the pillar 60 in the direction along the Y direction except a portion through which the pillar 60 penetrates. In addition, a width of the gate electrode 30 in the direction along the Y direction exceeds the width of the pillar 60 in the direction along the Y direction at the penetrating portion of the pillar 60.

That is, the width of the gate electrode 30 in the direction along the Y direction is wider at the portion through which the pillar 60 penetrates than at other portions. Accordingly, an outer periphery of the pillar 60 is surrounded by the gate electrode 30.

An insulating layer 31 having the same pattern as the plurality of gate electrodes 30 is provided on an upper surface of the gate electrodes 30. The insulating layer 31 as the third insulating layer is a layer containing a material different from a material of the insulating layers 20 and 40, and when the insulating layers 20 and 40 are, for example, silicon oxide layers, the insulating layer 31 may be a silicon nitride layer or the like.

The insulating layer 40 that covers the entirety of the plurality of gate electrodes 30 with the insulating layer 31 interposed therebetween is provided on the gate electrodes 30. The insulating layer 40 as the second insulating layer may be formed of the same material as the insulating layer 20, and is, for example, a SiO layer or a Low-k layer such as a SiOC layer or an air gap layer. A space between the gate electrodes 30 adjacent to each other in the Y direction is filled with the insulating layer 40.

The insulating layer 50 such as a SiO layer is provided on the insulating layer 40. A plurality of the upper electrodes 51 are provided on a lower surface side of the insulating layer 50 at positions overlapping a plurality of the lower electrodes 11 in the Z direction. As with the lower electrodes 11, the upper electrodes 51 are, for example, an ITO layer or the like, and are connected to the bit lines 70 further above the insulating layer 50 via a plug 52 penetrating the insulating layer 50. A plurality of the bit lines 70 extend in the direction along the Y direction and are arranged at predetermined intervals in the X direction.

At a position interposed between the lower electrode 11 and the upper electrode 51, the insulating layer 40, the gate electrode 30 corresponding to the position, and a plurality of the pillars 60 penetrating the insulating layer 20 are provided. Each of the plurality of pillars 60 has a channel layer 61 and a gate insulating layer 62.

The channel layer 61 as a semiconductor layer penetrates the insulating layer 40, the gate electrode 30, and the insulating layer 20 and is connected to the lower electrode 11 and the upper electrode 51. The channel layer 61 is a composite oxide semiconductor layer such as an IGZO layer, which is an oxide layer of indium (In), gallium (Ga), and zinc (Zn), and is provided in a central portion, which is the core, of the pillar 60.

The channel layer 61 of the individual pillars 60 has a tapered shape in which a cross-sectional area when viewed in a stacking direction of the insulating layer 40, the gate electrode 30, and the insulating layer 20, that is, an area of a cross section along an XY plane decreases downward at height positions of the insulating layer 40, the gate electrode 30, and the insulating layer 20. However, the channel layer 61 may have a straight shape with a substantially constant cross-sectional area in the XY plane at the height position of at least any of the insulating layer 40, the gate electrode 30, and the insulating layer 20.

In addition, the cross-sectional area of the channel layer 61 in the XY plane at the height position of the gate electrode 30 is generally smaller than the cross-sectional area of the channel layer 61 in the XY plane at the height position of the insulating layer 40 and the cross-sectional area of the channel layer 61 in the XY plane at the height position of the insulating layer 20.

That is, for example, when a cross-sectional shape of the channel layer 61 in the XY plane is substantially circular, it can be said that a diameter of the channel layer 61 is enlarged at the height positions of the insulating layers 20 and 40. In addition, center positions of the channel layer 61 in the XY plane are substantially coincident at the respective height positions of the insulating layer 40, the gate electrode 30, and the insulating layer 20, and the cross-sectional shape of the channel layer 61 in the XY plane at these height positions has a substantially concentric arrangement.

In addition, the cross-sectional area of the channel layer 61 in the XY plane changes discontinuously at an interface between the insulating layer 40 and the gate electrode 30 and at an interface between the gate electrode 30 and the insulating layer 20. Accordingly, a side wall of the channel layer 61 at the height position of the gate electrode 30 has a step protruding toward the center of the pillar 60 in the XY plane at height positions of the interface with the insulating layer 40 and the interface with the insulating layer 20.

The gate insulating layer 62 is, for example, a SiO layer, and covers the side wall of the channel layer 61 with a substantially uniform thickness. As a result, an outer shape of the gate insulating layer 62 is a shape in which the channel layer 61 is enlarged in the XY plane, that is, a shape substantially similar to the channel layer 61. Therefore, a size relationship at each height position of the cross-sectional area of the gate insulating layer 62 in the XY plane substantially coincides with the size relationship at each height position of the above-described cross-sectional area of the channel layer 61 in the XY plane. The outer shape of the gate insulating layer 62 is also an outer shape of the pillar 60.

Here, in both end portions of the pillar 60 in the direction along the Y direction at a height position of a lower surface of the insulating layer 40 and both end portions in the direction along the Y direction on the upper surface of the gate electrode 30 surrounding the pillar 60, outer shapes on at least one end side may overlap to substantially coincide with each other when viewed in the Z direction.

In addition, the outer shape of the pillar 60 has, for example, a substantially concentric arrangement at the height position of the lower surface of the insulating layer 40 and the height position of the upper surface of the gate electrode 30 as described above. Therefore, since the outer shapes of the gate electrode 30 and the pillar 60 on at least one end side substantially coincide with each other when viewed in the Z direction, the gate electrode 30 covers the pillar 60 with a substantially uniform thickness on at least one side in the direction along the Y direction.

The gate insulating layer 62 may partially cover an outer edge of a lower surface of the channel layer 61. In this case, a lower end portion of the gate insulating layer 62 may have a shape that slightly protrudes toward the center of the pillar 60 in the Y plane. Even in such a case, conduction between the channel layer 61 and the lower electrode 11 is ensured at a central portion of a lower surface of the channel layer 61 in the XY plane.

As described above, the side wall of the channel layer 61 has a step at the height positions of the interface with the insulating layer 40 and the interface with the insulating layer 20. The gate insulating layer 62 may discontinuously cover the side wall of the channel layer 61 at the stepped portion of the side wall of the channel layer 61, which is at the interface with the insulating layer 40. Meanwhile, the gate insulating layer 62 continuously covers the side wall of the channel layer 61 at the stepped portion of the side wall of the channel layer 61, which is at the interface with the insulating layer 20.

When the gate insulating layer 62 discontinuously covers the side wall of the channel layer 61 at the interface with the insulating layer 40, a lower surface of the stepped portion of the channel layer 61 protruding to the upper surface side of the gate electrode 30 may come into contact with the upper surface of the gate electrode 30 at the interface with the insulating layer 40. The insulating layer 31 described above is interposed between the stepped portion of the channel layer 61 and the upper surface of the gate electrode 30, so that the contact between the stepped portion of the channel layer 61 and the upper surface of the gate electrode 30 is prevented.

As described above, the semiconductor device 1 is configured as, for example, a vertical transistor. That is, the vertical transistor may be turned on by applying a predetermined voltage from the gate electrode 30 to the channel layer 61 of the pillar 60 penetrating the gate electrode 30.

Each of the pillars 60, and the lower electrode 11, the gate electrode 30, and the upper electrode 51 connected to each of the pillars 60 may be regarded as one vertical transistor, so that the semiconductor device 1 may be considered to include a plurality of vertical transistors. In addition, in the vertical transistor, it can also be said that the gate electrode 30 that applies a voltage to the channel layer 61 functions as a word line.

### Method of Manufacturing Semiconductor Device

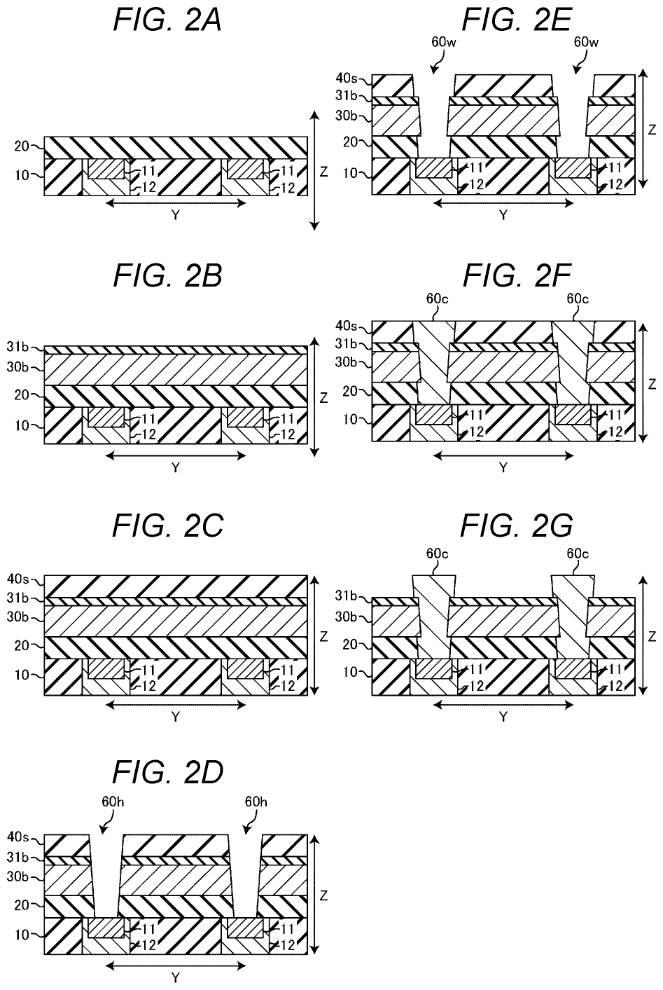

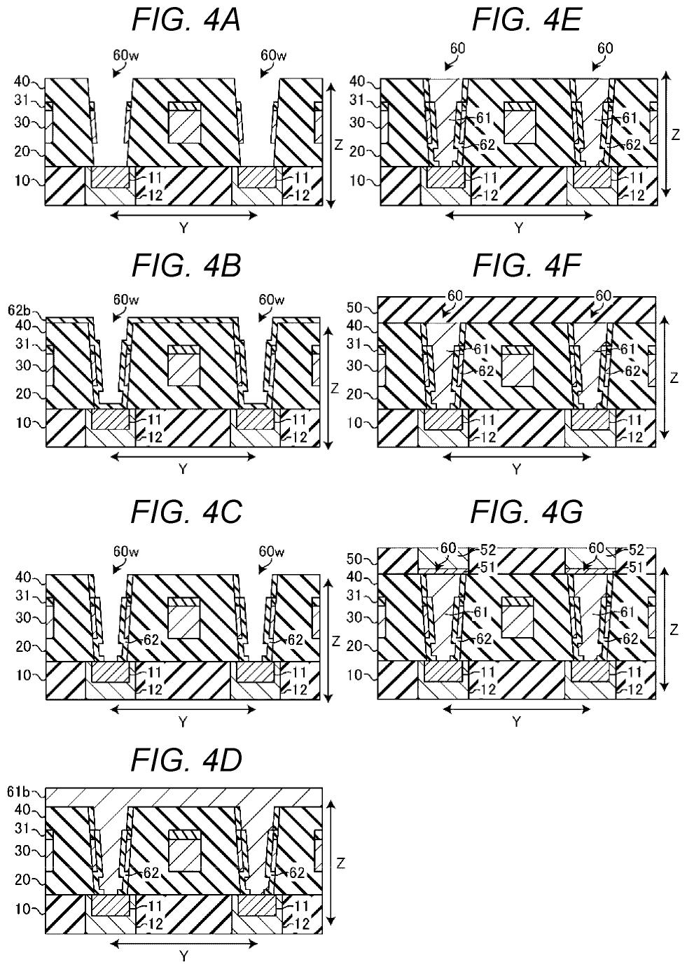

Next, an example of a method of manufacturing the semiconductor device 1 of Embodiment 1 will be described with reference to FIG. 2A to FIG. 4G. FIG. 2A to FIG. 4G are cross-sectional views sequentially illustrating a part of a procedure of the method of manufacturing the semiconductor device 1 according to Embodiment 1. More specifically, FIGS. 2A to 2G and FIGS. 4A to 4G are cross-sectional views taken along the Y direction of the semiconductor device 1 in the middle of manufacturing.

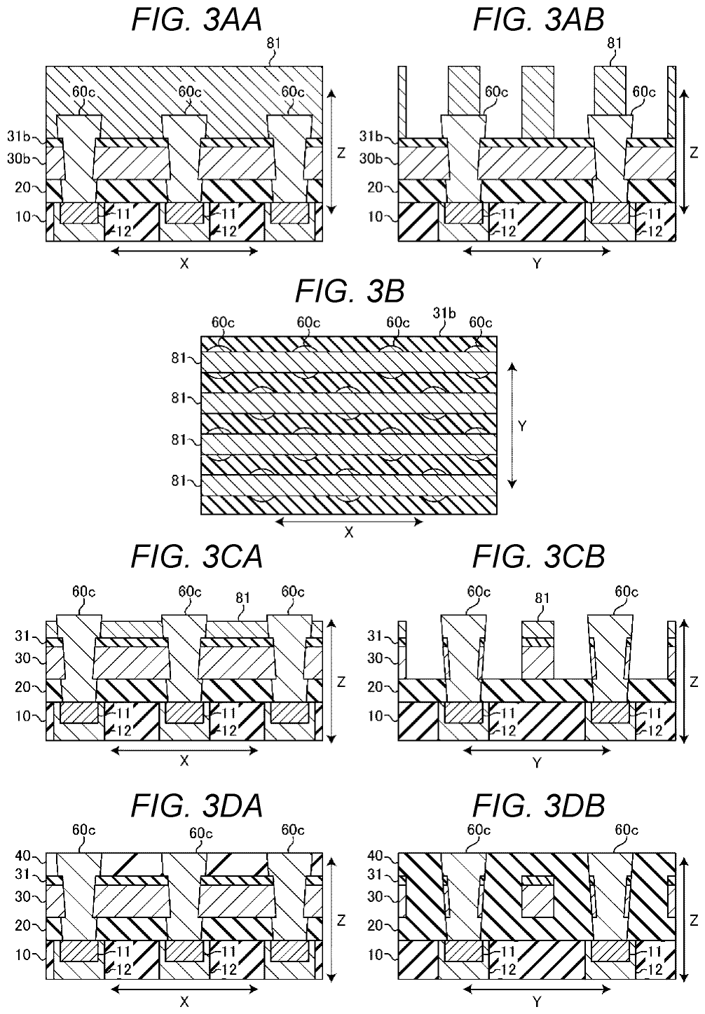

In addition, FIGS. 3AA, 3CA, and 3DA are cross-sectional views taken along the X direction of the semiconductor device 1 in the middle of manufacturing, FIGS. 3AB, 3CB, and 3DB are cross-sectional views taken along the Y direction of the semiconductor device 1 in the middle of manufacturing, and FIG. 3B is an XY cross-sectional view of the semiconductor device 1 in the middle of manufacturing at a height position of an insulating layer 40s to be described below.

As shown in FIG. 2A, the insulating layer 10 such as a silicon nitride layer is formed above the substrate. In addition, the plurality of contacts 12 penetrating the insulating layer 10 and the lower electrodes 11 as the plurality of first electrodes embedded in the contacts 12 are formed.

In addition, the insulating layer 20 as the first insulating layer such as a SiO layer or a Low-k layer that covers the upper surfaces of the insulating layer 10, the contacts 12, and the lower electrodes 11 is formed.

As shown in FIG. 2B, a gate electrode layer 30b such as a tungsten layer is formed on the insulating layer 20. In addition, an insulating layer 31b as a fourth insulating layer such as a silicon nitride layer is formed on the gate electrode layer 30b. The gate electrode layer 30b is a layer that is subsequently processed into a line shape extending in the direction along the X direction to be formed as the gate electrode 30. The insulating layer 31b is a layer that is subsequently processed into the same pattern as the gate electrode 30 to be formed as the insulating layer 31 that covers the upper surface of the gate electrode 30.

As shown in FIG. 2C, an insulating layer 40s as the second insulating layer such as a SiO layer is formed on the insulating layer 31b. The insulating layer 40s is a temporary layer that is subsequently replaced with the insulating layer 40 described above.

As shown in FIG. 2D, a plurality of through-holes 60h that penetrate the insulating layers 40s and 31b, the gate electrode layer 30b, and the insulating layer 20 and reach the lower electrode 11 are formed at positions overlapping the plurality of lower electrodes 11 in the Z direction.

The through-hole 60h has, for example, a tapered shape in which a cross-sectional area in the XY plane decreases from an upper end portion toward a lower end portion. The through-hole 60h may have a straight shape with a substantially constant cross-sectional area of the through-hole 60h in the XY plane at the height position of at least any of the insulating layer 40s, the gate electrode layer 30b, and the insulating layer 20.

As shown in FIG. 2E, the insulating layers 40s and 20 exposed on a side wall of the through-hole 60h are retreated by isotropic etching. At this time, a condition is used in which a selectivity between the gate electrode layer 30b, which is a metal layer such as a tungsten layer, and the insulating layer 31b containing a material different from that of the insulating layers 40s and 20 is ensured. As an example, wet etching using diluted hydrofluoric acid (DHF) may be used for the above-described process.

As a result, a through-hole 60w whose cross-sectional area in the XY plane at the height positions of the insulating layers 40s and 20 is enlarged is formed. More specifically, by the above-described process, the through-hole 60w having an outer shape that substantially coincides with that of the above-described pillar 60 is obtained.

As shown in FIG. 2F, the through-hole 60w is filled with a sacrificial layer such as an amorphous layer to form a pillar 60c. The pillar 60c is formed of a sacrificial layer or the like, and has a temporary structure having an outer shape that substantially coincides with that of the above-described pillar 60.

As shown in FIG. 2G, the insulating layer 40s is removed. At this time as well, as in the case of processing the through-hole 60h described above, isotropic etching such as wet etching using, for example, DHF may be used. As a result, a selectivity between the sacrificial layer filling the pillar 60c and the insulating layer 31b below the insulating layer 40s is obtained, an upper surface of the gate electrode layer 30b is exposed, and the pillar 60c protrudes from an upper surface of the insulating layer 31b.

As shown in FIGS. 3AA, 3AB, and 3B, a patterned resist 81 having a line pattern extending in the direction along the X direction and arranged at predetermined intervals in the Y direction is formed at a position overlapping the pillar 60c in the Z direction.

At this time, the patterned resist 81 is formed such that a width of each line of the patterned resist 81 in the direction along the Y direction, that is, a width of each line in a direction intersecting the extension direction is narrower than a width of the pillar 60c in the direction along the Y direction. Accordingly, when viewed in the Z direction, at least one end portion of the pillar 60c in the direction along the Y direction is exposed from each line of the patterned resist 81.

More specifically, when a displacement amount of the patterned resist 81 in the Y direction with respect to the pillar 60c is sufficiently small, both end portions of the pillar 60c are exposed from each line of the patterned resist 81. When the displacement amount of the patterned resist 81 in the Y direction is equal to or greater than a predetermined value, one end portion of both end portions of the pillar 60c is exposed from each line of the patterned resist 81, and the other end portion is covered with the patterned resist 81.

As shown in FIGS. 3CA and 3CB, the insulating layer 31b and the gate electrode layer 30b are etched using the patterned resist 81 and a portion of the pillar 60c exposed from the patterned resist 81 as a mask. Accordingly, the plurality of gate electrodes 30 extending in the direction along the X direction and the insulating layer 31 processed into a pattern of the gate electrode 30 and covering the upper surfaces of the individual gate electrodes 30 are formed.

More specifically, the patterned resist 81 is transferred to the pattern of the gate electrode 30 except a portion through which the pillar 60c penetrates. Accordingly, the gate electrode 30 has a width in the direction along the Y direction that is narrower than, for example, the width of the pillar 60c in the direction along the Y direction except the penetrating portion of the pillar 60c.

On the other hand, in the portion through which the pillar 60c penetrates, a partial shape of a portion of the pillar 60c protruding from the gate electrode 30 is transferred to the pattern of the gate electrode 30. Accordingly, the gate electrode 30 has a width in the Y direction that is equal to or larger than the width of the pillar 60c in the direction along the Y direction at the height position of the gate electrode 30 in the penetrating portion of the pillar 60c.

More specifically, when the displacement amount of the patterned resist 81 in the Y direction with respect to the pillar 60c is sufficiently small and both end portions of the pillar 60c in the direction along the Y direction protrude from the patterned resist 81, the width of the gate electrode 30 in the direction along the Y direction substantially coincides with the width of the portion of the pillar 60c protruding from the gate electrode 30 in the direction along the Y direction in the penetrating portion of the pillar 60c. In addition, in this case, the gate electrode 30 covers the pillar 60c with a substantially uniform thickness at both end portions in the direction along the Y direction.

In addition, when the displacement amount of the patterned resist 81 in the Y direction is large, one end portion of the pillar 60c protrudes from the patterned resist 81, and the other end portion is covered with the patterned resist 81, the width of the gate electrode 30 in the direction along the Y direction is larger than the width of the portion of the pillar 60c protruding from the gate electrode 30 in the direction along the Y direction in the penetrating portion of the pillar 60c. In addition, in this case, the gate electrode 30 covers the pillar 60c with a substantially uniform thickness at one end portion in the direction along the Y direction.

As described above, the pattern of the gate electrode 30 is formed by using a self-alignment method using, as a mask, the upper end portion of the pillar 60c whose diameter is enlarged. Therefore, the gate electrode 30 covers the entire circumference of the pillar 60c.

When processing the insulating layer 31b and the gate electrode layer 30b, it is preferable to use, for example, anisotropic etching such as reactive ion etching (RIE). Accordingly, a dimension conversion difference in the width of the individual gate electrodes 30 in the direction along the Y direction can be reduced.

Thereafter, the remaining patterned resist 18 is removed by, for example, ashing using oxygen plasma.

As shown in FIGS. 3DA and 3DB, the insulating layer 40 as the third insulating layer such as a SiO layer or a Low-k layer is formed to cover the entirety of the gate electrode 30 having the insulating layer 31 on the upper surface.

As shown in FIG. 4A, the sacrificial layer filling the pillar 60c is removed by wet etching or the like. As a result, the through-hole 60w whose diameter is enlarged in the portion of the insulating layers 20 and 40 is formed again.

As shown in FIG. 4B, a gate insulating layer 62b such as a SiO layer that covers a side wall and a bottom surface of each of a plurality of the through-holes 60w is formed. At this time, the gate insulating layer 62b continuously covers the side wall of the through-hole 60w having a step at a height position of an interface between the insulating layers 20 and 40 and the gate electrode 30, and also covers an upper surface of the insulating layer 40.

As shown in FIG. 4C, the gate insulating layer 62b is removed from the bottom surface of each of the plurality of through-holes 60w. Accordingly, the gate insulating layer 62b is also removed from the upper surface of the insulating layer 40, and the gate insulating layer 62 covering the side wall of each of the plurality of through-holes 60w is formed.

The gate insulating layer 62b is removed from the bottom surface of the through-hole 60w by, for example, anisotropic etching such as RIE. At this time, a cross-sectional area of the through-hole 60w in the XY plane is narrower at the height position of the gate electrode 30 than at the height positions of the insulating layers 20 and 40.

Therefore, at the height position of the upper surface of the gate electrode 30, a part or entirety of the gate insulating layer 62b formed in a stepped portion protruding to the center of the through-hole 60w in the XY plane is removed. In addition, etching of the gate insulating layer 62b on the outer edge portion of the bottom surface of the through-hole 60w is inhibited by the side wall portion of the through-hole 60w narrowed inward at the height position of the gate electrode 30. Therefore, the gate insulating layer 62b may not be removed from the entire bottom surface of the through-hole 60w, and the gate insulating layer 62b may remain at the outer edge portion of the bottom surface of the through-hole 60w.

As shown in FIG. 4D, each of the plurality of through-holes 60w is filled with a semiconductor layer 61b such as an IGZO layer using, for example, an atomic layer deposition (ALD) method. At this time, the semiconductor layer 61b also covers the upper surface of the insulating layer 40.

As shown in FIG. 4E, the semiconductor layer 61b on the upper surface of the insulating layer 40 is removed by chemical mechanical polishing (CMP) or the like. As a result, the semiconductor layer 61b is separated into individual layers to form the above-described channel layer 61. In addition, as a result, a plurality of pillars 60 including the channel layer 61 and the gate insulating layer 62 are formed.

Here, as described above, the pattern of the gate electrode 30 is formed by using a self-alignment method using, as a mask, the upper end portion of the pillar 60c whose diameter is enlarged. Therefore, both end portions of the pillar 60 in the Y direction are more reliably covered with the gate electrode 30.

As shown in FIG. 4F, the insulating layer 50 such as a SiO layer that covers the insulating layer 40 and the upper surfaces of the plurality of pillars 60 is formed.

As shown in FIG. 4G, a plurality of upper electrodes 51 and a plurality of plugs 52 that penetrate the insulating layer 50 and are connected to the upper electrodes 51 are formed in the insulating layer 50.

As described above, the semiconductor device 1 of Embodiment 1 is manufactured.

### Overview

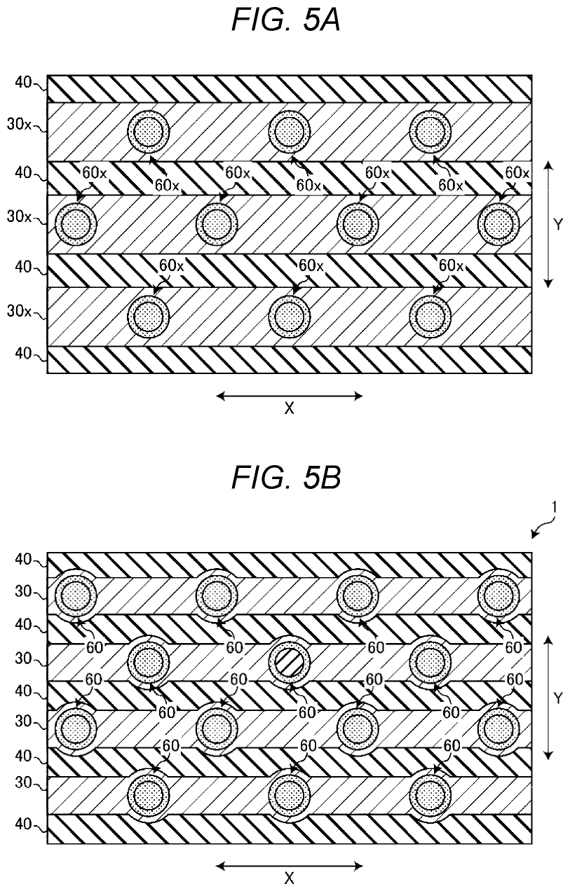

In a semiconductor device configured as a vertical transistor, miniaturization is achieved. At this time, it is desired to make a plurality of gate electrodes extending in a line shape and arranged at predetermined intervals thinner and denser. FIGS. 5A and 5B show a layout of a gate electrode of a semiconductor device of a comparative example.

FIGS. 5A and 5B are XY cross-sectional views at height positions of gate electrodes 30 and 30x of semiconductor devices according to an embodiment and a comparative example. More specifically, FIG. 5A is an XY cross-sectional view of the semiconductor device of the comparative example, and FIG. 5B is an XY cross-sectional view of the semiconductor device 1 of Embodiment 1, which is re-shown for comparison.

In the semiconductor device of the comparative example shown in FIG. 5A, for example, a plurality of gate electrodes 30x extending in the X direction and arranged at predetermined intervals are first formed, and through-holes are provided at positions overlapping the gate electrodes 30x in the Z direction to form pillars 60x. When forming the through-holes, the gate electrode 30x is formed such that a width in the Y direction is larger than a width of the pillar 60x in the Y direction as a whole, in consideration of occurrence of displacement between a patterned resist serving as a mask and the gate electrode 30x. In addition, an interval between the plurality of gate electrodes 30x arranged in the Y direction is set to a predetermined distance or more, and a breakdown voltage between the plurality of gate electrodes 30x is ensured.

As described above, with the method of the comparative example, it is difficult to make the gate electrode 30x thin and to arrange the gate electrodes 30x at high density.

Therefore, it is conceivable to adopt a method of forming a pattern of the gate electrode by using a self-alignment method. In this case, for example, a pillar filled with a sacrificial layer is made to protrude from an upper surface of a gate electrode layer. In addition, a spacer layer is provided on an outer periphery of the protruding portion from the gate electrode layer of the pillar. Furthermore, a line-shaped patterned resist having a diameter smaller than a diameter including the spacer layer of the pillar is formed at a position overlapping the pillar in the Z direction, and the gate electrode may be formed using the patterned resist and the spacer layer of the pillar as a mask.

However, in such a method, the process becomes complicated due to the process of forming the spacer layer around the pillar, the process of removing the spacer layer after the gate electrode is formed, and the like, and the number of processes increases, so that the manufacturing cost of the semiconductor device increases.

According to the method of manufacturing a semiconductor device of the embodiment, the through-hole 60h that penetrates the insulating layer 40s, the gate electrode layer 30b, and the insulating layer 20 to reach the lower electrode 11 is formed, the insulating layers 20 and 40s exposed on the side wall of the through-hole 60w are isotropically etched, the cross-sectional area of the through-hole 60h when viewed in the stacking direction of the insulating layer 40s, the gate electrode layer 30b, and the insulating layer 20 is enlarged at the height positions of the insulating layers 20 and 40s, and the through-hole 60w whose cross-sectional area is enlarged is filled with the sacrificial layer.

Accordingly, the pillar 60c whose diameter is enlarged can be easily formed above the gate electrode layer 30b. That is, for example, a process of providing a spacer layer on the outer periphery of the pillar filled with the sacrificial layer and then removing the spacer layer can be omitted.

According to the method of manufacturing a semiconductor device of the embodiment, the patterned resist 81 is formed in which the width in the direction along the Y direction is narrower than the width of the pillar 60c filled with the sacrificial layer in the direction along the Y direction. In addition, the gate electrode layer 30b is processed using the pillar 60c as a mask together with the patterned resist 81 to form the gate electrode 30 such that the width in the direction along the Y direction at a position overlapping the pillar 60c in the stacking direction of each layer is wider than that of other portions.

Accordingly, the periphery of the pillar 60 can be covered with the gate electrode 30 having a sufficient layer thickness while the gate electrode 30 is made thin.

According to the method of manufacturing a semiconductor device of the embodiment, the gate electrode 30 is obtained which has a wider width at the penetrating portion of the channel layer 61 than at other portions in the direction along the Y direction. At this time, the gate electrode 30 covers at least one of both end portions of the channel layer 61 in the direction along the Y direction with a substantially uniform thickness. Accordingly, the plurality of gate electrodes 30 can be disposed at high density.

According to the semiconductor device of the embodiment, the channel layer 61 has a cross-sectional area that discontinuously changes at the height position of the interface between the insulating layer 40 and the gate electrode 30 when viewed from the stacking direction of each layer. In addition, the gate insulating layer 62 may discontinuously cover the side wall of the channel layer 61 at the interface between the insulating layer 40 and the gate electrode 30.

According to the semiconductor device of the embodiment, the insulating layer 31 containing a material different from that of the insulating layers 20 and 40 is further provided between the gate electrode 30 and the insulating layer 40. Accordingly, even when the upper end portion of the pillar 60 covers the gate electrode 30, and the gate insulating layer 62 in the portion is partially interrupted, the lower end portion of the channel layer 61 that covers the gate electrode 30 is prevented from coming into contact with the gate electrode 30.

According to the semiconductor device of the embodiment, the gate insulating layer 62 continuously covers the side wall of the channel layer 61 at the interface between the insulating layer 20 and the gate electrode 30. As described above, the pillar 60 also protrudes to the gate electrode 30 side at the height position of the insulating layer 20. Meanwhile, the gate insulating layer 62 continuously covers this portion, so that the contact between the channel layer 61 and the gate electrode 30 is also prevented in this portion.

### Embodiment 2

Hereinafter, Embodiment 2 will be described in detail with reference to the drawings. Embodiment 2 is different from Embodiment 1 described above in that the upper end portion of the pillar has a tapered shape.

In the following drawings, the same configurations as those in Embodiment 1 described above may be denoted by the same reference numerals, and the description thereof may be omitted.

### Structure Example of Semiconductor Device

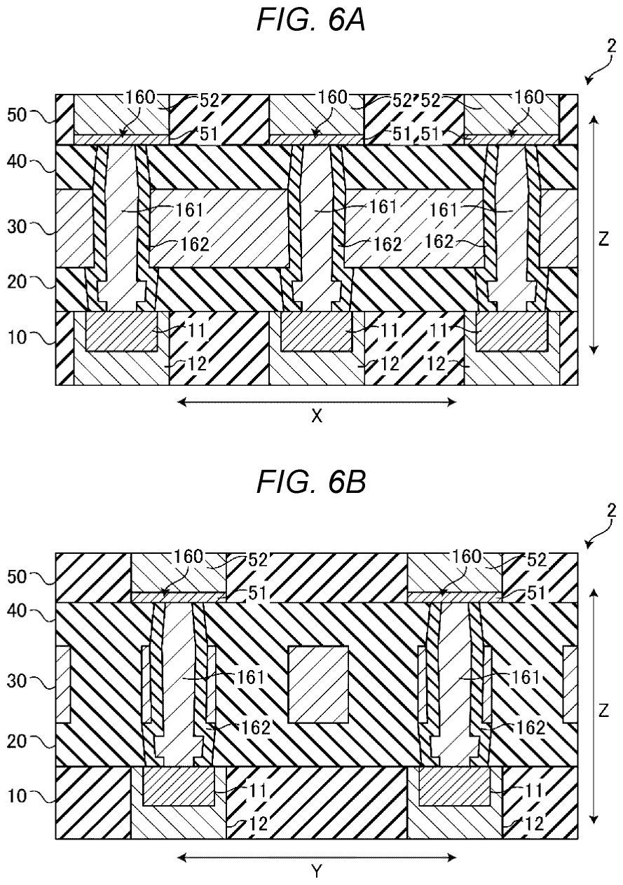

FIGS. 6A and 6B are schematic diagrams showing an example of a configuration of a semiconductor device 2 according to Embodiment 2. FIG. 6A is a cross-sectional view of the semiconductor device 2 in the X direction. FIG. 6B is a cross-sectional view of the semiconductor device 2 in the Y direction.

As shown in FIGS. 6A and 6B, the semiconductor device 2 includes a plurality of pillars 160 having a tapered shape at the upper end portion at the height position of the insulating layer 40. Each of the plurality of pillars 160 has a channel layer 161 and a gate insulating layer 162.

The channel layer 161 as a semiconductor layer penetrates the insulating layer 40, the gate electrode 30, and the insulating layer 20 and is connected to the lower electrode 11 and the upper electrode 51. The channel layer 161 is a composite oxide semiconductor layer such as an IGZO layer, and is provided in a central portion, which is the core, of the pillar 160.

The channel layer 161 of the individual pillars 160 has a tapered shape in which a cross-sectional area when viewed in a stacking direction of the gate electrode 30 and the insulating layer 20, that is, an area of a cross section along an XY plane decreases downward at height positions of the gate electrode 30 and the insulating layer 20. The channel layer 161 may have a straight shape with a substantially constant cross-sectional area in the XY plane at the height position of at least any of the gate electrode 30 and the insulating layer 20.

In addition, the individual channel layers 161 have a tapered shape in which the area of the cross section along the XY plane increases downward at the height position of the insulating layer 40.

In addition, the cross-sectional area of the channel layer 161 in the XY plane at the height position of the gate electrode 30 is generally larger than the cross-sectional area of the channel layer 161 in the XY plane at the height position of the insulating layer 40, and is generally smaller than the cross-sectional area of the channel layer 161 in the XY plane at the height position of the insulating layer 20.

That is, for example, when a cross-sectional shape of the channel layer 161 in the XY plane is substantially circular, it can be said that a diameter of the channel layer 161 is reduced at the height position of the insulating layer 40 and is enlarged at the height position of the insulating layer 20. In addition, center positions of the channel layer 161 in the XY plane are substantially coincident at the respective height positions of the insulating layer 40, the gate electrode 30, and the insulating layer 20, and the cross-sectional shape of the channel layer 161 in the XY plane at these height positions has a substantially concentric arrangement.

In addition, the cross-sectional area of the channel layer 161 in the XY plane changes discontinuously at the interface between the insulating layer 40 and the gate electrode 30. In addition, at the interface between the gate electrode 30 and the insulating layer 20, the cross-sectional area of the channel layer 161 in the XY plane changes discontinuously.

Accordingly, a side wall of the channel layer 161 at the height position of the gate electrode 30 has a step protruding toward the center of the pillar 160 in the XY plane at a height position of the interface with the insulating layer 20.

The gate insulating layer 162 is, for example, a SiO layer, and covers the side wall of the channel layer 161 with a substantially uniform thickness. As a result, an outer shape of the gate insulating layer 162 is a shape substantially similar to that of the channel layer 161 enlarged in the XY plane. Therefore, a size relationship at each height position of the cross-sectional area of the gate insulating layer 162 in the XY plane substantially coincides with the size relationship at each height position of the above-described cross-sectional area of the channel layer 161 in the XY plane. The outer shape of the gate insulating layer 162 is also an outer shape of the pillar 160.

The gate insulating layer 162 continuously covers the side wall of the channel layer 161 at both the interface portion between the insulating layer 40 and the gate electrode 30 and the stepped portion of the side wall of the channel layer 161 at the interface with the insulating layer 20.

The gate insulating layer 162 may partially cover an outer edge of a lower surface of the channel layer 161. Even in such a case, conduction between the channel layer 161 and the lower electrode 11 is ensured at a central portion of a lower surface of the channel layer 161 in the XY plane.

As described above, the semiconductor device 2 is configured as, for example, a vertical transistor. That is, the vertical transistor may be turned on by applying a predetermined voltage from the gate electrode 30 to the channel layer 161 of the pillar 160 penetrating the gate electrode 30. Method of Manufacturing Semiconductor Device

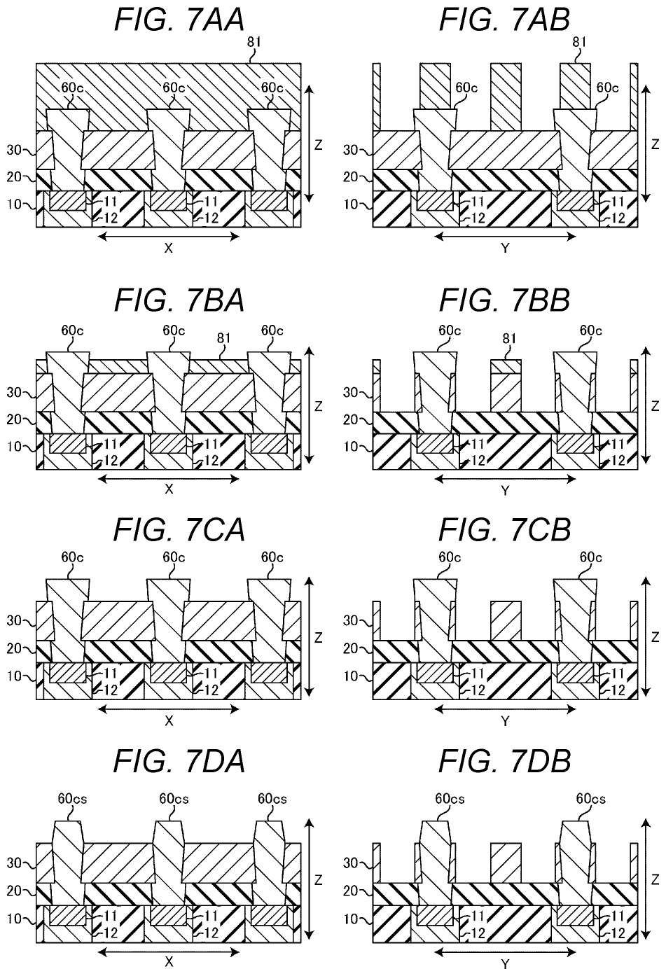

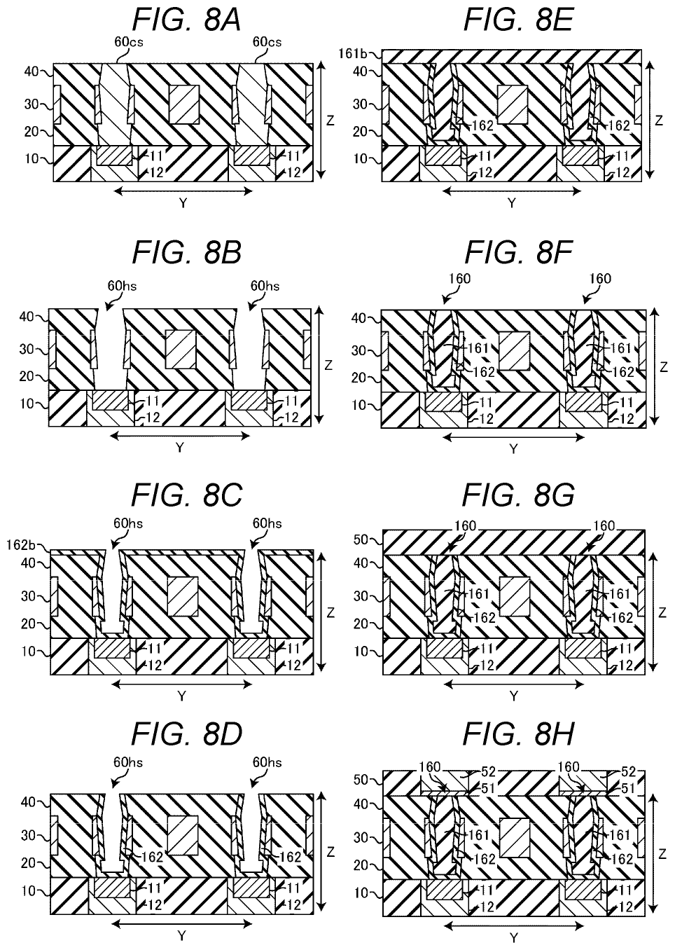

Next, an example of a method of manufacturing the semiconductor device 2 of Embodiment 2 will be described with reference to FIGS. 7AA to 7DB and FIGS. 8A to 8H.

FIGS. 7AA to 7DB and FIGS. 8A to 8H are cross-sectional diagrams sequentially illustrating a part of a procedure of the method for manufacturing the semiconductor device 2 according to Embodiment 2. FIGS. 7AA, 7BA, 7CA, and 7DA are cross-sectional views taken along the X direction of the semiconductor device 2 in the middle of manufacturing, and FIGS. 7AB, 7BB, 7CB, and 7DB are cross-sectional views taken along the Y direction of the semiconductor device 2 in the middle of manufacturing. FIGS. 8A to 8H are cross-sectional views taken along the Y direction of the semiconductor device 2 in the middle of manufacturing.

In the method of manufacturing the semiconductor device 2 of Embodiment 2 as well, for example, the processing of FIGS. 2A to 2G is performed as in Embodiment 1 described above. Accordingly, the pillar 60c, whose upper and lower ends are enlarged, filled with the sacrificial layer is formed.

As shown in FIGS. 7AA and 7AB, as in Embodiment 1 described above, the patterned resist 81 having a line pattern extending in the direction along the X direction and arranged at predetermined intervals in the Y direction is formed at a position overlapping the pillar 60c in the Z direction. Each line of the patterned resist 81 has a width in the direction along the Y direction that is narrower than the width of the pillar 60c in the direction along the Y direction.

As shown in FIGS. 7BA and 7BB, as in Embodiment 1 described above, the gate electrode layer 30b is etched using the patterned resist 81 and the portion of the pillar 60c exposed from the patterned resist 81 as a mask. As a result, the plurality of gate electrodes 30 extending in the direction along the X direction are formed.

As shown in FIGS. 7CA and 7CB, the remaining patterned resist 18 is removed by, for example, ashing using oxygen plasma.

In Embodiment 1 described above, the insulating layer 40 is then formed, the sacrificial layer of the pillar 60c is removed, and the pillar 60 is formed by die-cutting the through-hole 60w whose diameter is enlarged at the upper and lower ends. In Embodiment 2, as will be described below, the shape of the pillar 60c is further processed before the insulating layer 40 is formed.

As shown in FIGS. 7DA and 7DB, the upper end portion of the pillar 60c protruding from the gate electrode 30 is thinned by anisotropic etching such as RIE. As a result, a pillar 60cs having a tapered shape in which the cross-sectional area of the protruding portion from the gate electrode 30 in the XY plane increases downward is formed.

At this time, it is preferable that the entire sacrificial layer in the portion whose diameter is enlarged is removed at a lower end portion of the protruding portion of the pillar 60cs, that is, at the height position of the upper surface of the gate electrode 30. Accordingly, the pillar 60cs has a shape in which the cross-sectional area in the XY plane continuously changes at the height position of the upper surface of the gate electrode 30. In addition, by removing the sacrificial layer in the portion whose diameter is enlarged, the upper surface of the gate electrode 30 that covers both end portions of the pillar 60cs in the direction along the Y direction is exposed.

The subsequent processing is performed, for example, in the same manner as in Embodiment 1 described above, as described below.

As shown in FIG. 8A, the insulating layer 40 such as a SiO layer or a Low-k layer is formed to cover the entirety of the gate electrode 30.

As shown in FIG. 8B, the sacrificial layer filling the pillar 60cs is removed by wet etching or the like. Accordingly, a through-hole 60hs having a tapered shape whose diameter is enlarged in the insulating layer 20 portion and whose upper end portion is narrowed in the insulating layer 40 portion is formed.

As shown in FIG. 8C, a gate insulating layer 162b such as a SiO layer that covers a side wall and a bottom surface of each of a plurality of the through-holes 60hs is formed. At this time, the gate insulating layer 162b continuously covers the side wall of the through-hole 60hs having a step at a height position of an interface between the insulating layer 20 and the gate electrode 30, and also covers an upper surface of the insulating layer 40.

As shown in FIG. 8D, the gate insulating layer 162b is removed from the bottom surface of each of the plurality of through-holes 60hs. Accordingly, the gate insulating layer 162b is also removed from the upper surface of the insulating layer 40, and the gate insulating layer 162 covering the side wall of each of the plurality of through-holes 60hs is formed.

As described above, at the height position of the interface between the insulating layer 40 and the gate electrode 30, the cross-sectional area of the through-hole 60hs in the XY plane continuously changes, and the side wall of the through-hole 60hs has no step. Therefore, the gate insulating layer 162 maintains a state in which it continuously covers the entire side wall of the through-hole 60hs without being interrupted at the height position of the interface between the insulating layer 40 and the gate electrode 30.

As shown in FIG. 8E, each of the plurality of through-holes 60hs is filled with a semiconductor layer 161b such as an IGZO layer by using, for example, an ALD method. At this time, the semiconductor layer 161b also covers the upper surface of the insulating layer 40.

As shown in FIG. 8F, the semiconductor layer 161b on the upper surface of the insulating layer 40 is removed by CMP or the like. As a result, the semiconductor layer 161b is separated into individual layers to form the above-described channel layer 161. In addition, as a result, a plurality of pillars 160 including the channel layer 161 and the gate insulating layer 162 are formed.

As shown in FIG. 8G, the insulating layer 50 such as a SiO layer that covers the insulating layer 40 and the upper surfaces of the plurality of pillars 160 is formed.

As shown in FIG. 8H, a plurality of upper electrodes 51 and a plurality of plugs 52 that penetrate the insulating layer 50 and are connected to the upper electrodes 51 are formed in the insulating layer 50.

As described above, the semiconductor device 2 of Embodiment 2 is manufactured.

### Overview

In Embodiment 1 described above, the pillar 60 whose diameter is enlarged at both height positions of the insulating layers 20 and 40 is formed, and the insulating layer 31 is held on the upper surface of the gate electrode 30 to prevent the contact between the channel layer 61 in the diameter-enlarged portion of the pillar 60 and the upper surface of the gate electrode 30. Meanwhile, the method of preventing the contact between the channel layer and the gate electrode is not limited thereto.

According to the method of manufacturing the semiconductor device 2 of Embodiment 2, after forming the gate electrode 30 and before forming the insulating layer 40, a cross-sectional area of the upper end portion of the pillar 60c when viewed in the stacking direction of each layer is reduced by anisotropic etching.

Accordingly, the pillar 160 having no step on the side wall can be formed at the interface between the insulating layer 40 and the gate electrode 30, and the gate insulating layer 162 can continuously cover the side wall of the channel layer 161 at this portion. Therefore, the channel layer 161 of the pillar 160 is prevented from coming into contact with the upper surface of the gate electrode 30.

In addition, since the insulating layer 31 and the like are not provided on the upper surface of the gate electrode 30, the wiring capacitance between the gate electrodes 30 arranged in the Y direction can be reduced. Since the channel layer 161 does not protrude to the upper surface of the gate electrode 30, the wiring capacitance of the gate electrode 30 can be further reduced.

According to the semiconductor device 2 and the method of manufacturing the same of Embodiment 2, the same effects as those of the semiconductor device 1 and the method of manufacturing the same of Embodiment 1 described above are obtained.

### Modification Example

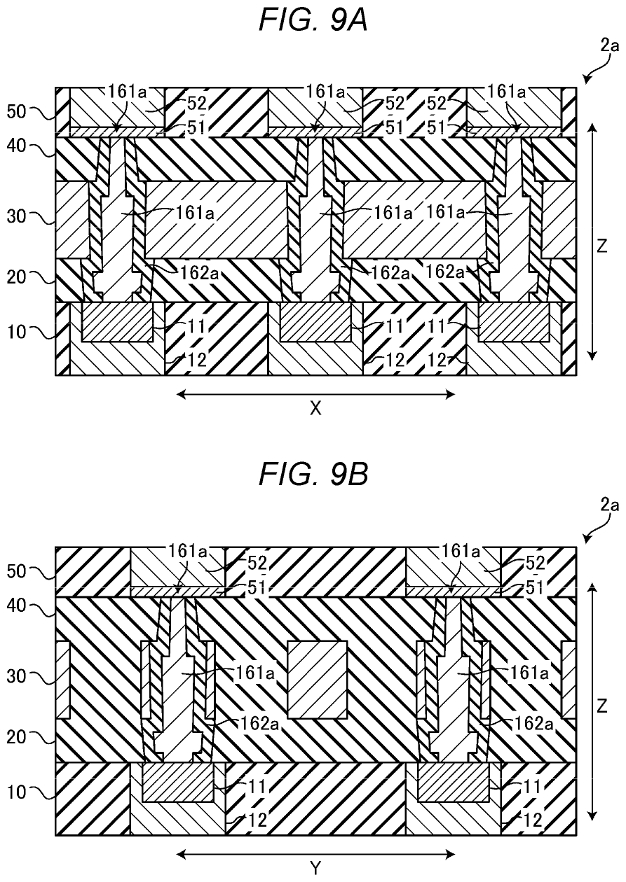

Next, a semiconductor device 2a of a modification example of Embodiment 2 will be described with reference to FIGS. 9A and 9B. The semiconductor device 2a of the modification example is different from Embodiment 2 described above in that the semiconductor device 2a includes a pillar 160a having a step on the side wall at the interface between the insulating layer 40 and the gate electrode 30.

FIGS. 9A and 9B are schematic diagrams showing an example of a configuration of the semiconductor device 2a according to the modification example of Embodiment 2. FIG. 9A is a cross-sectional view taken along the X direction of the semiconductor device 2a. FIG. 9B is a cross-sectional view taken along the Y direction of the semiconductor device 2a. In FIGS. 9A and 9B, the same configurations as those in Embodiment 1 described above may be denoted by the same reference numerals, and the description thereof may be omitted.

In Embodiment 2 described above, at the interface between the insulating layer 40 and the gate electrode 30, the cross-sectional area of the channel layer 161 in the XY plane continuously changes, and the pillar 160 has no step in the side wall of this portion.

As shown in FIGS. 9A and 9B, in the semiconductor device 2a of the modification example, the cross-sectional area of the channel layer 161a in the XY plane is smaller at the height position of the lower surface of the insulating layer 40 than at the height position of the upper surface of the gate electrode 30. At this time, the cross-sectional area of the channel layer 161a in the XY plane discontinuously changes at the interface between the insulating layer 40 and the gate electrode 30, and the side wall of the channel layer 161a at the height position of the gate electrode 30 has a step protruding toward the outside of the pillar 60 at the height position of the interface with the insulating layer 40.

A gate insulating layer 162a is, for example, a SiO layer, and covers the side wall of the channel layer 161a with a substantially uniform thickness. As a result, an outer shape of the gate insulating layer 162a is a shape substantially similar to that of the channel layer 161a enlarged in the XY plane. The outer shape of the gate insulating layer 162a is also an outer shape of the pillar 160a.

The gate insulating layer 162a continuously covers the side wall of the channel layer 161a at both stepped portions of the side wall of the channel layer 161a at the interfaces with the insulating layers 20 and 40. The gate insulating layer 162a may partially cover an outer edge of a lower surface of the channel layer 161a.

The pillar 160a having the above-described shape can be obtained, for example, by extending the time of the process shown in FIGS. 7DA and 7DB of Embodiment 2 described above. That is, excessive over-etching is performed on the pillar 160c by anisotropic etching such as RIE, thereby further promoting thinning of the pillar 160c.

As a result, at the height position of the upper surface of the gate electrode 30, the cross-sectional area in the XY plane discontinuously changes, and a pillar of the sacrificial layer having a step on the side wall of this portion is obtained. After that, in the through-hole obtained by removing the sacrificial layer and also in the pillar 160a finally obtained, the cross-sectional area in the XY plane discontinuously changes at the interface between the insulating layer 40 and the gate electrode 30, and the side wall of this portion has a step.

As described above, the semiconductor device 2a of the modification example is manufactured.

According to the semiconductor device 2a of the modification example, the channel layer 161a has a cross-sectional area that discontinuously changes at the height position of the interface between the insulating layer 40 and the gate electrode 30 when viewed from the stacking direction of each layer. As a result, the contact between the channel layer 161a of the pillar 160a and the upper surface of the gate electrode 30 can be more reliably prevented.

According to the semiconductor device 2a of the modification example, the same effects as those of the semiconductor device 2 and the method of manufacturing the same of Embodiment 2 described above are obtained.

### APPENDICES

Hereinafter, preferred aspects of the present disclosure are additionally described.

### Appendix 1

According to one aspect of the present disclosure, there is provided a semiconductor device including: a first electrode; a first insulating layer provided on the first electrode; a second insulating layer provided above the first insulating layer; a second electrode provided on the second insulating layer to face the first electrode; a gate electrode that extends in a region between the first and second insulating layers interposed between the first and second electrodes in a first direction intersecting a stacking direction of the first and second insulating layers; a channel layer that penetrates the gate electrode and extends in the stacking direction and that has one end connected to the first electrode and the other end connected to the second electrode; and a gate insulating layer provided between the first insulating layer, the gate electrode, and the second insulating layer, and the channel layer, in which the channel layer has a larger cross-sectional area at a height position of the first insulating layer than at a height position of the gate electrode when viewed in the stacking direction of the first insulating layer, the gate electrode, and the second insulating layer, and the gate electrode has a wider width at a penetrating portion of the channel layer than at other portions in a second direction intersecting the stacking direction and the first direction.

### Appendix 2

In the semiconductor device according to Appendix 1, the channel layer has a larger cross-sectional area at a height position of the second insulating layer than at the height position of the gate electrode when viewed in the stacking direction.

### Appendix 3

In the semiconductor device according to Appendix 2, the channel layer has a cross-sectional area that discontinuously changes at a height position of an interface between the second insulating layer and the gate electrode when viewed in the stacking direction.

### Appendix 4

In the semiconductor device according to Appendix 3, the gate insulating layer discontinuously covers a side wall of the channel layer at the interface between the second insulating layer and the gate electrode.

### Appendix 5

In the semiconductor device according to Appendix 1, the channel layer has a larger cross-sectional area that discontinuously changes at a height position of an interface between the first insulating layer and the gate electrode when viewed in the stacking direction.

### Appendix 6

In the semiconductor device according to Appendix 5, the gate insulating layer continuously covers a side wall of the channel layer at the interface between the first insulating layer and the gate electrode.

### Appendix 7

In the semiconductor device according to Appendix 1, the channel layer has a smaller cross-sectional area at a height position of the second insulating layer than at the height position of the gate electrode when viewed in the stacking direction.

### Appendix 8

In the semiconductor device according to Appendix 7, the channel layer has a tapered shape in which a cross-sectional area when viewed in the stacking direction increases from an upper end portion toward a lower end portion at the height position of the second insulating layer.

### Appendix 9

In the semiconductor device according to Appendix 7, the gate insulating layer continuously covers a side wall of the channel layer from an upper end portion to a lower end portion of the channel layer.

### Appendix 10

In the semiconductor device according to Appendix 9, the channel layer has a cross-sectional area that discontinuously changes at a height position of an interface between the first insulating layer and the gate electrode when viewed in the stacking direction.

### Appendix 11

In the semiconductor device according to Appendix 9, the channel layer has a cross-sectional area that discontinuously changes at a height position of an interface between the second insulating layer and the gate electrode when viewed in the stacking direction.

### Appendix 12

In the semiconductor device according to Appendix 1, the channel layer includes a composite oxide semiconductor.

### Appendix 13

According to another aspect of the present disclosure, there is provided a method of manufacturing a semiconductor device, the method including: forming a first insulating layer, a gate electrode layer, and a second insulating layer in this order on a first electrode; forming a through-hole that penetrates the second insulating layer, the gate electrode layer, and the first insulating layer to reach the first electrode; isotropically etching the first and second insulating layers exposed on a side wall of the through-hole to enlarge a cross-sectional area of the through-hole when viewed in a stacking direction of the first insulating layer, the gate electrode layer, and the second insulating layer at height positions of the first and second insulating layers; filling the through-hole whose cross-sectional area is enlarged with a sacrificial layer; removing the second insulating layer to cause the sacrificial layer to protrude from an upper surface of the gate electrode layer; forming a mask pattern extending in a first direction intersecting the stacking direction at a position overlapping the sacrificial layer in the stacking direction; processing the gate electrode layer using the mask pattern as a mask to form a gate electrode extending in the first direction; forming a third insulating layer that covers the gate electrode up to a protrusion height of the sacrificial layer from the gate electrode; and removing the sacrificial layer to form a channel layer in the through-hole.

### Appendix 14

In the method of manufacturing a semiconductor device according to Appendix 13, after forming the gate electrode and before forming the third insulating layer, a cross-sectional area of an upper end portion of the sacrificial layer when viewed in the stacking direction is reduced by anisotropic etching.

### Appendix 15

In the method of manufacturing a semiconductor device according to Appendix 14, when performing the anisotropic etching, the sacrificial layer is processed such that a portion protruding from the gate electrode has a tapered shape in which a cross-sectional area when viewed in the stacking direction increases from an upper end portion to a lower end portion.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
a first insulating layer provided over the first electrode in a stacking direction;
a second insulating layer provided over the first insulating layer in the stacking direction;
a second electrode provided over the second insulating layer in the stacking direction;
a gate electrode interposed between the first and second insulating layers in the stacking direction, and extending in a first direction intersecting the stacking direction;
a channel layer penetrating the gate electrode, extending in the stacking direction, having a first end connected to the first electrode, and having a second end connected to the second electrode; and
a gate insulating layer provided between the first insulating layer, the gate electrode, and the second insulating layer, and the channel layer,
wherein the channel layer has a first cross-sectional area at a height position of the first insulating layer and a second cross-sectional area at a height position of the gate electrode, the first cross-sectional area is larger than the second cross-sectional area, and
the gate electrode has a wider width at a penetrating portion of the channel layer than any other portions in a second direction intersecting the stacking direction and the first direction.

2. The semiconductor device according to claim 1,
wherein the gate electrode covers at least one of both end portions of the channel layer in the second direction with a substantially uniform thickness.

3. The semiconductor device according to claim 1,
wherein the channel layer has a third cross-sectional area at a height position of the second insulating layer, the third cross-sectional area is also larger than the second cross-sectional area.

4. The semiconductor device according to claim 3, further comprising:
a third insulating layer provided between the gate electrode and the second insulating layer and containing a material different from a material of the first and second insulating layers.

5. The semiconductor device according to claim 1,
wherein the channel layer has a fourth cross-sectional area at a height position of the second insulating layer, the fourth cross-sectional area is smaller than the second cross-sectional area.

6. A method of manufacturing a semiconductor device, the method comprising:
sequentially forming, on a first electrode, a first insulating layer, a gate electrode layer, and a second insulating layer in a stacking direction;
forming a through-hole that penetrates the second insulating layer, the gate electrode layer, and the first insulating layer to expose the first electrode;
isotropically etching the first and second insulating layers exposed on a side wall of the through-hole to enlarge a cross-sectional area of the through-hole at height positions of the first and second insulating layers;
filling the through-hole with a sacrificial layer;
removing the second insulating layer, causing the sacrificial layer to protrude from an upper surface of the gate electrode layer;
forming a mask pattern extending in a first direction intersecting the stacking direction at a position overlapping the sacrificial layer in the stacking direction;
processing the gate electrode layer using the mask pattern as a mask to form a gate electrode extending in the first direction;
forming a third insulating layer that covers the gate electrode up to a protrusion height of the sacrificial layer from the gate electrode; and
removing the sacrificial layer to form a channel layer in the through-hole.

7. The method of manufacturing a semiconductor device according to claim 6,
wherein, when forming the mask pattern, a mask pattern is formed in which a width in a second direction intersecting the stacking direction and the first direction is narrower than a width in the second direction in a protruding portion of the sacrificial layer, and
when forming the gate electrode, the gate electrode layer is processed using the sacrificial layer as the mask together with the mask pattern to form the gate electrode such that a width in the second direction at the position overlapping the sacrificial layer in the stacking direction is wider than widths of other portions.

8. The method of manufacturing a semiconductor device according to claim 6,
wherein, before forming the channel layer,
a gate insulating layer that covers the side wall and a bottom surface of the through-hole is formed, and
the gate insulating layer is removed from the bottom surface of the through-hole.

9. The method of manufacturing a semiconductor device according to claim 8,
wherein, before forming the second insulating layer, a fourth insulating layer containing a material different from a material of the first and third insulating layers is formed on the gate electrode layer, and
when forming the through-hole, the through-hole is made to penetrate the second insulating layer, the fourth insulating layer, the gate electrode layer, and the first insulating layer.

10. The method of manufacturing a semiconductor device according to claim 6,
wherein, after forming the gate electrode and before forming the third insulating layer, a cross-sectional area of an upper end portion of the sacrificial layer when viewed in the stacking direction is reduced by anisotropic etching.

11. A semiconductor device comprising:
a first electrode;
a first insulating layer provided over the first electrode in a stacking direction;
a second insulating layer provided over the first insulating layer in the stacking direction;
a second electrode provided over the second insulating layer in the stacking direction;
a gate electrode interposed between the first and second insulating layers in the stacking direction, and extending in a first direction intersecting the stacking direction;
a channel layer penetrating the gate electrode, extending in the stacking direction, having a first end connected to the first electrode, and having a second end connected to the second electrode; and
a gate insulating layer provided between the first insulating layer, the gate electrode, and the second insulating layer, and the channel layer,
wherein the channel layer has a first cross-sectional area aligned with the first insulating layer, a second cross-sectional area aligned with the gate electrode, and a third cross-sectional area aligned with second insulating layer,
at least one of the first cross-sectional area or the third cross-sectional area is larger than the second cross-sectional area, and
the gate electrode has an expanded width in a second direction intersecting the stacking direction and the first direction, the expanded width is wider than any other portion of the gate electrode along the extending first direction.
